(19) United States
(12) Patent Application Publication
(10) Pub. No.: US 2013/0340801 A1
(43) Pub. Date: Dec. 26, 2013

(54) Thermoelectric Power Generation System Using Gradient Heat Exchanger

(71) Applicant: GMZ Energy Inc., Waltham, MA (US)

(72) Inventors: Yanliang Zhang, Waltham, MA (US); James Christopher Caylor, Melrose, MA (US); Michael Kozlowski, Boston, MA (US); Bed Poudel, Brighton, MA (US)

(21) Appl. No.: 13/924,826

(22) Filed: Jun. 24, 2013

Related U.S. Application Data
(60) Provisional application No. 61/664,012, filed on Jun. 25, 2012.
(60) Provisional application No. 61/766,300, filed on Feb. 19, 2013.

(51) Int. Cl. H01L 35/30

(52) U.S. Cl. CPC H01L 35/30
USPC 136/201; 136/212; 136/205

(57) ABSTRACT

A power generating system comprising a heat exchanger comprising an inlet, an outlet and a conduit extending along a length of the heat exchanger between the inlet and the outlet, and a plurality of thermally conductive fins provided within the conduit, a packing fraction of the fins increasing from a first packing fraction proximate the inlet to a second packing fraction proximate the outlet; and a plurality of thermoelectric power generators positioned along the length of the heat exchanger, each thermoelectric power generator comprising a hot side, a cold side and a thermoelectric element extending there between, wherein the hot sides of the thermoelectric power generators are in thermal contact with the plurality of fins such that the temperature of each hot side is substantially equal along the length of the heat exchanger.

### RELATED APPLICATION

This application claims the benefit of priority to U.S. Provisional Application No. 61/664,012, filed on Jun. 25, 2012, and to U.S. Provisional Application No. 61/766,300, filed on Feb. 19, 2013, the entire contents of which are incorporated by reference herein.

### BACKGROUND

Thermoelectric converters, such as solar thermoelectric converters are known in the art. These converters rely upon the Seebeck effect to convert temperature differences into electricity. A portion of the thermoelectric converter may be directly or indirectly heated by a heat source, such as a hot gas stream, to create the necessary temperature difference. The efficiency of the energy conversion depends upon the temperature difference across the thermoelectric converter. Greater temperature differences allow for greater conversion efficiency.

### SUMMARY

Embodiments may include a power generating system comprising a heat exchanger comprising an inlet, an outlet and a conduit extending along a length of the heat exchanger between the inlet and the outlet, and a plurality of thermally conductive fins provided within the conduit, a packing fraction of the fins increasing from a first packing fraction proximate the inlet to a second packing fraction proximate the outlet; and a plurality of thermoelectric power generators positioned along the length of the heat exchanger, each thermoelectric power generator comprising a hot side, a cold side and a thermoelectric element extending therebetween, wherein the hot sides of the thermoelectric power generators are in thermal contact with the plurality of fins such that the temperature of each hot side is substantially equal along the length of the heat exchanger.

In various embodiments, the temperatures of the hot sides may be within approximately 20° C. or less of each other, such as within approximately 12° C. of each other (e.g., between 0-12° C. of each other) between the inlet and the outlet portions of the heat exchanger.

Further embodiments include a method of generating power that includes heating a fluid using a source of thermal energy, flowing the heated fluid through a heat exchanger comprising a plurality of thermally conductive fins in thermal contact with the fluid flow, wherein a packing fraction of the fins increases in the predominant direction of fluid flow through the heat exchanger, and generating electrical power using a plurality of thermoelectric power generators positioned along a length of the heat exchanger, each thermoelectric power generator comprising a hot side, a cold side and a thermoelectric element extending therebetween, wherein the hot sides of the thermoelectric power generators are in thermal contact with the plurality of fins such that the temperature of each hot side is substantially equal along the length of the heat exchanger.

Further embodiments include a thermoelectric module that includes an electrically interconnected plurality of p-type and n-type thermoelectric material legs, wherein each leg extends between a first side and a second side of the module, a cover located over the thermoelectric material legs on a first side of the module and configured to conduct thermal energy from an external heat source to the thermoelectric material legs, and a plurality of thermally conductive fins directly attached to an outer surface of the module cover.

Further embodiments include a method of generating electrical energy using a thermoelectric module comprising a plurality of thermoelectric material legs having a hot side and a cold side, where the method includes conducting heat from a heat source to the hot side of each of the thermoelectric material legs via a plurality of thermally conductive fins directly attached to an outer surface of a module cover located over the hot sides of the legs to provide a temperature differential between the hot side and the cold side of the legs, and generating electricity from the plurality of thermoelectric material legs using the temperature differential.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1A is a schematic cross sectional perspective view of a power generating system having a plurality of thermoelectric power generators (TEG) and a gradient heat exchanger for maintaining a generally uniform temperature at a first side of the plurality of thermoelectric generators (TEG) over the flow stream.

FIG. 1B is a plot showing the temperature of the exhaust gas (Tₑₓₕₐᵤₛₜ) and of the hot side of the TEG modules (T_{TEG-H}) along the direction of exhaust flow.

FIG. 2 is cross sectional perspective view of the gradient heat exchanger of FIG. 1A illustrating the increasing fin packing faction along the direction of fluid flow.

FIG. 3 is a cross-sectional perspective view of the power generating system of FIG. 1A.

FIG. 4 is a cross-sectional perspective view of a gradient heat exchanger with an increasing plate fin packing fraction along the direction of fluid flow

FIG. 5 is a perspective view of a thermoelectric generator module having heat exchange fins attached directly to the module casing.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Multiple methods exist for generating electricity from heat energy. Various embodiments may include thermoelectric conversion elements. Thermoelectric conversion relies on the Seebeck effect to convert temperature differences into electricity. Thermoelectric converters operate more efficiently under greater temperature differences.

A thermoelectric power generation (TEG) system may use heat from a heat source to provide a temperature difference across one or more thermoelectric conversion elements and thereby generate electricity. The heat source may be, for example, a hot fluid flow stream, such as automobile exhaust, industrial waste heat, hot combustion product (e.g., a boiler flame), etc. A heat exchanger may be used to transfer heat from the flow stream to a first side (i.e., the “hot” side) of the thermoelectric conversion elements.

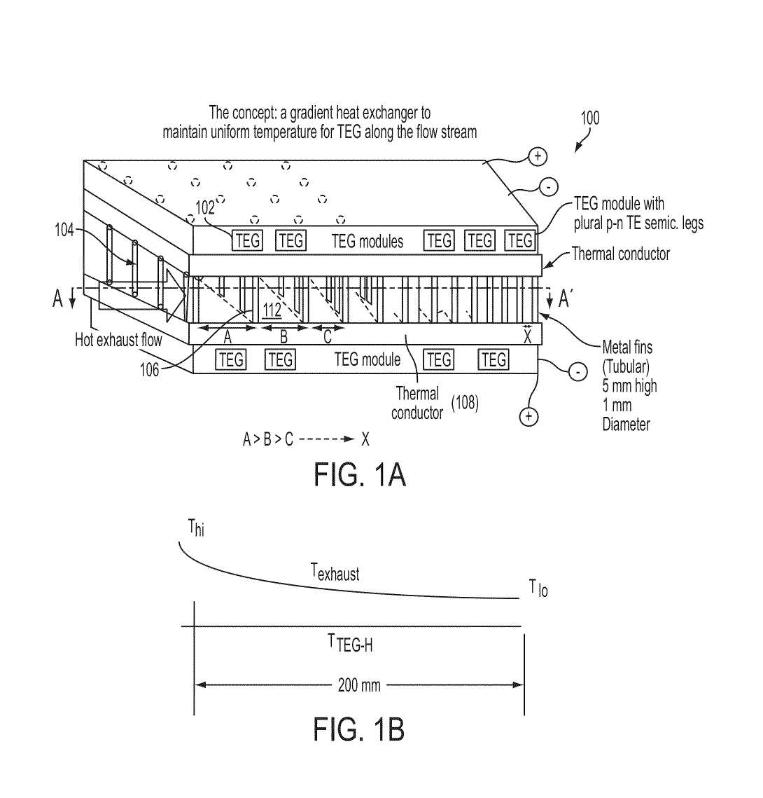

A challenge in heat exchanger design for TEG systems is that the temperature of the fluid flow tends to drop along the direction of fluid flow within the heat exchanger. This is illustrated in FIG. 1B, which illustrates the decreasing temperature of a hot exhaust flow from an inlet temperature (Tₕᵢ) to an outlet temperature (Tₗₒ). This temperature drop may cause decreased performance and inconsistent working conditions among the TEG modules of the power generation system.

Various embodiments include a power generating system having a plurality of thermoelectric power generators (TEG) and a gradient heat exchanger for maintaining a generally uniform temperature at a first side of the plurality of thermoelectric generators (TEG) over the flow stream. In various embodiments, the present system may provide a solution to the above-described problem which may significantly improve the cost performance of a TEG system, such as a TEG-based waste heat recovery system.

FIG. 1A is a schematic cross sectional perspective view of a power generating system 100 having a plurality of TEG modules 102 and a gradient heat exchanger 104 for transferring heat energy from a hot fluid flow (e.g., an exhaust gas flow) to a first side of the TEG modules (e.g., a “hot” side of the TEG modules). The heat exchanger 104 may include a plurality of fins 106, which may be tubular elements (e.g., pin fins) made of a thermally conductive material, such as metal. The fins 106 may be positioned within the flow stream of the hot fluid so that heat from the hot fluid is transferred to the fins 106. The fins 106 may be oriented generally perpendiclar to the direction of fluid flow. The fins 106 may extend between a pair of plates 108, 110, which may define a conduit 112 through which the fluid flows. The plates 108, 110 may be made of a thermally conductive material, such as metal, and may be made from the same material as the fins. In embodiments, the plates 108, 110 may be eliminated, and the fins 106 may extend directly between TEG modules 102, which may define the conduit through which the fluid flows.

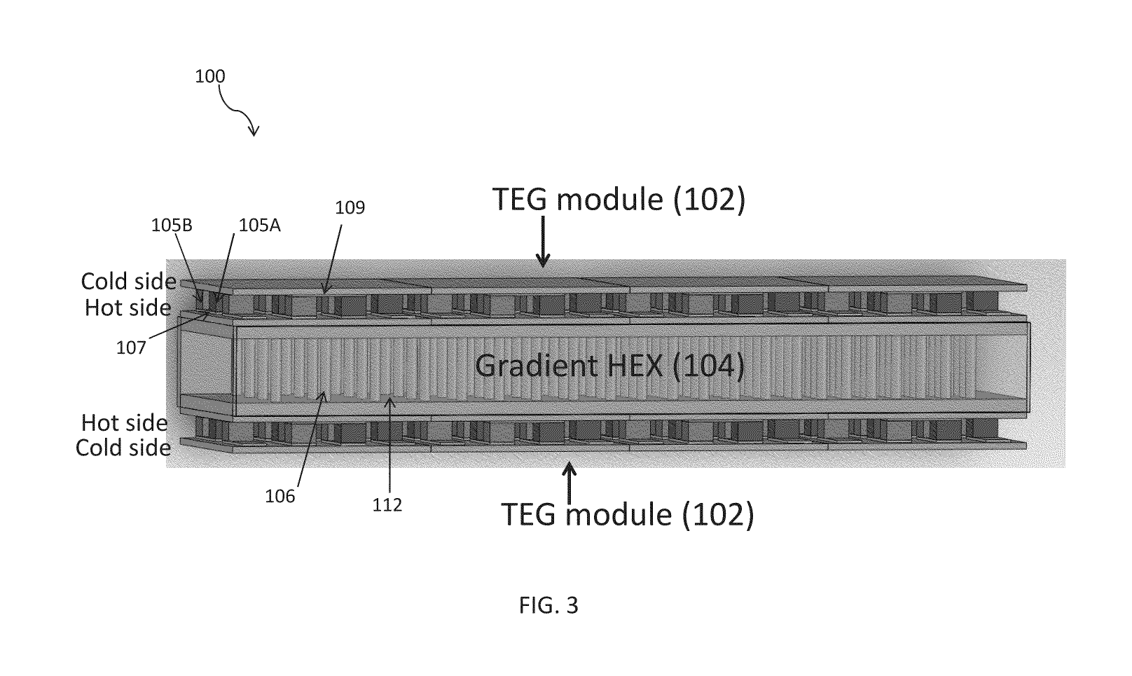

The TEG modules 102 may each include a first (hot) side, a second (cold) side, and a plurality of thermoelectric material elements (e.g., legs) disposed there between. As shown in FIG. 3, the modules 102 may each include a plurality of pairs of p-type thermoelectric material legs 105A and n-type thermoelectric material legs 105B. Each pair of legs 105A, 105B may be thermally and electrically coupled at a first (e.g., hot) end, e.g., to form a junction such as a pn junction or p-metal-n junction. The junction can be a header 107 made of an electrically conductive material, such as a metal. Electrical connectors 109 (e.g., metal connectors) may be connected to the second (e.g., cold) ends of the thermoelectric material legs 105A, 105B, and may be laterally offset from the header connector 107 such that for each pair of n-type and p-type legs, one leg 105A (e.g., a p-type leg) contacts a first connector 109, and the other leg 105B (e.g., an n-type leg) contacts a second connector 109. A module 102 may include a plurality of such leg pairs arranged in a desired circuit configuration (e.g., connected in series, in parallel, or in a combination series/parallel configuration). Electrical leads may be used to extract electrical energy from the module(s) 102.

The first, or “hot” side of the TEG modules 102 may be in direct or indirect thermal contact with the fins 106 of the heat exchanger 104. The second, or “cold” side of the TEG modules 102 may be substantially insulated from the fins 106, and may be in direct or indirect thermal contact with ambient air or a cooling fluid flow, for example. In embodiments, a cooling fluid (e.g., a liquid, such as water) may flow proximate to and in direct or indirect thermal contact with the cold sides the TEG modules 102 (e.g., within one or more separate conduits or pipes) in a counter-flow, co-flow and/or cross-flow configuration relative to the flow of hot fluid through the conduit 112 of the heat exchanger 104. In this manner, one end of the thermoelectric converters is maintained at an elevated temperature. With the opposed end of the converters exposed to a lower temperature, the thermoelectric converters generate electrical energy.

In various embodiments, the thermoelectric material legs 105A, 105B may be made from a variety of bulk materials and/or nanostructures. The thermoelectric materials can comprise, but are not limited to, one of: half-Heusler, Bi₂Te₃, Bi₂Te₃₋ₓSeₓ (n-type)/BiₓSe₂₋ₓTe₃(p-type), SiGe (e.g., Si₈₀Ge₂₀), PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, and combinations thereof. The materials may comprise compacted nanoparticles or nanoparticles embedded in a bulk matrix material. For example, see U.S. patent application Ser. No. 11/949,353 filed Dec. 3, 2007, which is incorporated herein by reference for all purposes, for a description of exemplary materials.

In preferred embodiments, the thermoelectric elements comprise half-Heusler materials. Suitable half-Heusler materials and methods of fabricating half-Heusler thermoelectric elements are described in U.S. patent application Ser. No. 13/330,216 filed Dec. 19, 2011 and Ser. No. 13/719,96 filed Dec. 19, 2012, the entire contents of both of which are incorporated herein by reference for all purposes. It has been discovered that the figure of merit of thermoelectric materials improves as the grain size in the thermoelectric material decreases. In one example of a method for fabricating thermoelectric materials, thermoelectric materials with nanometer scale (less than 1 micron) grains are produced, i.e., 95%, such as 100% of the grains have a grain size less than 1 micron. Preferably, the nanometer scale mean grain size is in a range of 10-300 nm. This method may be used to fabricate any thermoelectric material and includes making half-Heusler materials with nanometer scale grains. The method may be used to make both p-type and n-type half-Heusler materials. In one example, the half-Heusler material is n-type and has the formula Hf_{1+δ-x-y}ZrₓTi_{y}NiSn_{1+δ-z}Sb_{z}, where 0≦x≦1.0, 0≦y≦1.0, 0≦z≦1.0, and −0.1≦δ≦0.1 (to allow for slightly non-stoichiometric material), such as Hf_{1-x-y}ZrₓTi_{y}NiSn_{1-z}Sb_{z}, where 0≦x≦1.0, 0≦y≦1.0, and 0≦z≦1.0 when δ=0 (i.e., for the stoichiometric material). In another example, the half-Heusler is a p-type material and has the formula Hf_{1+δ-x-y}ZrₓTi_{y}CoSb_{1+δ-z}Sn_{z}, where 0≦x≦1.0, 0≦y≦1.0, 0≦z≦1.0, and −0.1≦δ≦0 (to allow for slightly non-stoichiometric material), such as Hf_{1-x-y}ZrₓTi_{y}CoSb_{1-z}Sn_{z}, where 0≦x≦1.0, 0≦y≦1.0, and 0≦z≦1.0 when δ=0 (i.e., for the stoichiometric material).

The fins 106 may have a generally circular cross-section as shown in FIG. 1A, although other cross-sections (e.g., polygonal, triangular, ovoid, irregularly shaped, etc.) may be utilized. In one embodiment, the fins 106 have a diameter of ˜1 mm, and may be about 5 mm in length. The length of the heat exchanger 104 in the direction of fluid flow may be approximately 200 mm in one embodiment. The fins 106 may also be plate type fins, as described below

An embodiment fin type heat exchanger may include a plurality of plate fins, pin fins, or both. A packing fraction of the fins may vary from a first packing fraction proximate the inlet to conduit 112 to a second denser packing fraction proximate the outlet of conduit 112, in order to provide a substantially uniform temperature to the hot sides of TEG modules 102. As shown in FIG. 1A, the density of the fins 106 may increase in the direction of hot fluid flow. The spacing of the fins 106 along the direction of hot fluid flow may increase from a first fin spacing (A), to a second fin spacing (B), to a third fin spacing (C), etc., where A>B>C . . . >x.

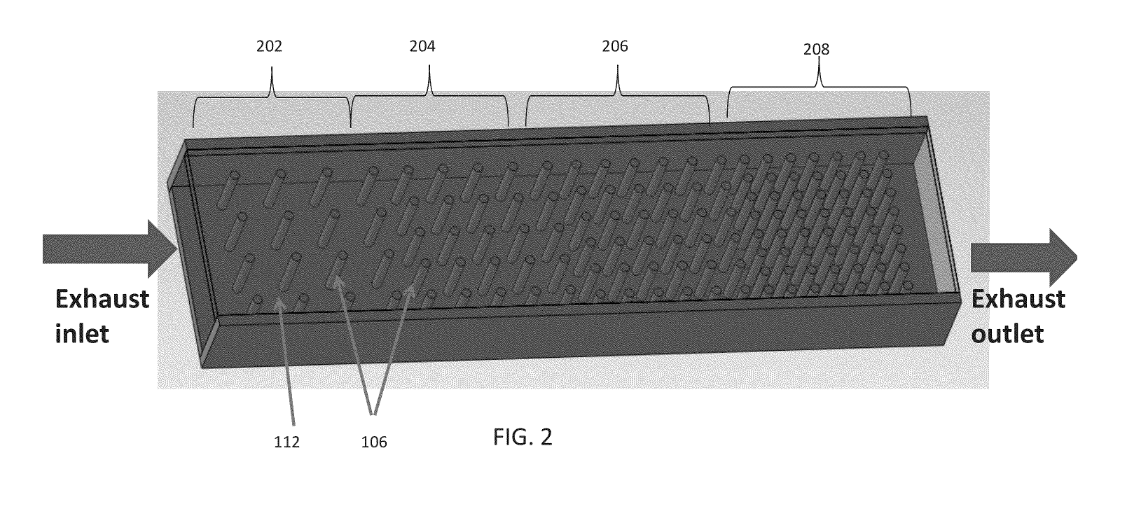

FIG. 2 illustrates the gradient heat exchanger 104 of FIG. 1A along line A-A′. As can be seen in FIG. 2, the spacing of the fins 106 (pin-type fins in this embodiment) may be varied both along the direction of fluid flow and in a direction transverse to fluid flow. In general, the fin packing fraction (i.e., fin density) may increase from a first packing fraction proximate the fluid inlet of the heat exchanger to a second packing fraction proximate the fluid outlet of the heat exchanger. The packing fraction may increase as a stepwise function, such as shown in FIG. 2, in which the heat exchanger includes four sections 202, 204, 206, 208 of gradually increasing fin packing fractions. In some embodiments, the fin packing fraction may be continuously graded over all or a portion of the length of the heat exchanger.

The packing fraction or density of the fins may be optimized to maintain substantially uniform temperature at the “hot” sides of the TEG modules 102. As used herein, “substantially uniform temperature” means that the temperatures of the hot sides may be within approximately 20° C. of each other, such as within approximately 10° C. of each other (e.g., between 0-10° C. of each other). In embodiments, the temperature drop across the hot sides of the TEG modules 102 may be less than 25% (e.g., 1-25%, such as 3-20%) of the temperature of the hot side of the module closest to the inlet of the heat exchanger. In embodiments, the temperature drop may be less than 10% (e.g., less than 5%, such as 3-5%) of the temperature of the hot side of the module closest to the heat exchanger inlet.

A comparison computer simulation between a TEG system with a conventional (i.e., uniform fin density) heat exchanger and a gradient heat exchanger is provided in Table 1 below.

| | TEG-in | TEG-out | Δ T | Heat flow | Pressure drop |
|---|---|---|---|---|---|
| | (° C.) | (° C.) | (° C.) | (W) | (Pa) |
| Uniform fin | 406 | 282 | 124 | 1226 | 302.2 |
| Gradient fin | 342 | 330 | 12 | 1160 | 300 |

In this example, the gradient fin heat exchanger reduced the TEG system temperature drop between the inlet and outlet from 124° C. to 12° C. (e.g., 20° C. or less temperature drop), while maintaining similar heat transfer performance and pressure drop. The temperature uniformity provides potential gains in the TEG system performances and significant reduction in system cost.

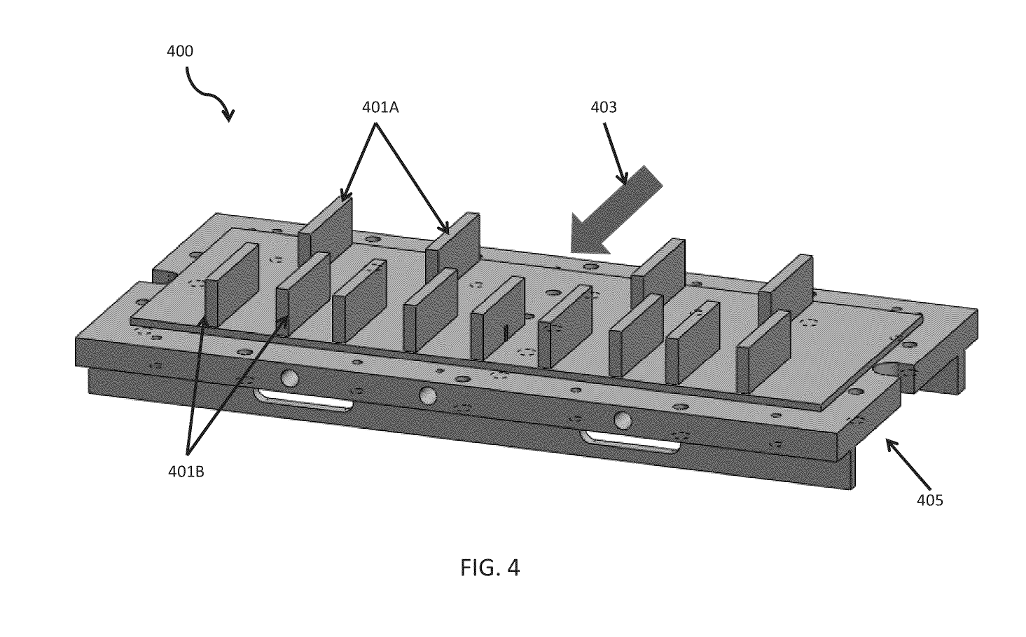

FIG. 4 illustrates an embodiment of a gradient fin heat exchanger 400 having a plurality of plate fins 401. In this embodiment, the fin packing fraction (i.e., fin density) of the plate fins 401 (e.g., the size of plate fins 401 and/or the spacing between plate fins 401) may be varied along the direction of fluid flow (indicated by arrow 403) as shown in FIGS. 1A and 2, and/or in a direction transverse to fluid flow, as shown in FIG. 4. In the embodiment of FIG. 4, a first group of plate fins 401A proximate the fluid inlet of the heat exchanger 400 has a first spacing between the plate fins 401A in a direction substantially perpendicular to the fluid flow, and a second group of plate fins 401B, located downstream of the first group along the direction of fluid flow 403, has a second spacing between the plate fins 401B in the direction substantially perpendicular to the fluid flow. The plate fins 401B of the second group are more closely spaced (i.e., have a higher packing fraction) in the direction substantially perpendicular to the fluid flow. Additional groups of plate fins having varying spacing may be provided downstream of fins 401B and/or upstream of fins 401A. Thus, the fins 401A in the row closer to the fluid inlet are spaced farther apart from each other than the fins 401B are spaced from each other in the row farther from the fluid inlet. In other words, the packing fraction of the fins 401A in a direction substantially perpendicular to an inlet to outlet direction (i.e., to the fluid flow direction) is lower in a first location than the packing fraction of the fins 401B in a second location farther from the inlet than the first location.

Each group of fins may be offset relative to the fins of the adjacent group(s) in the direction substantially parallel to the fluid flow, as shown in FIG. 4, to promote contact between the fluid flow and the fins. Alternatively, the fins may be aligned with the fins of the adjacent group(s). The packing fraction for each group of fins may increase in a continuous or stepwise fashion over all or a portion of the length of the heat exchanger. The heat exchanger 400 may include a mounting surface 405 to which one or more thermoelectric generator (TEG) modules may be mounted. The surface 405 is in thermal contact with the fins 401A, 401B. T he fins 401, 401B may be configured to provide a substantially uniform temperature across the mounting surface 405, so as to provide a substantially uniform temperature over the “hot” sides of the TEG elements.

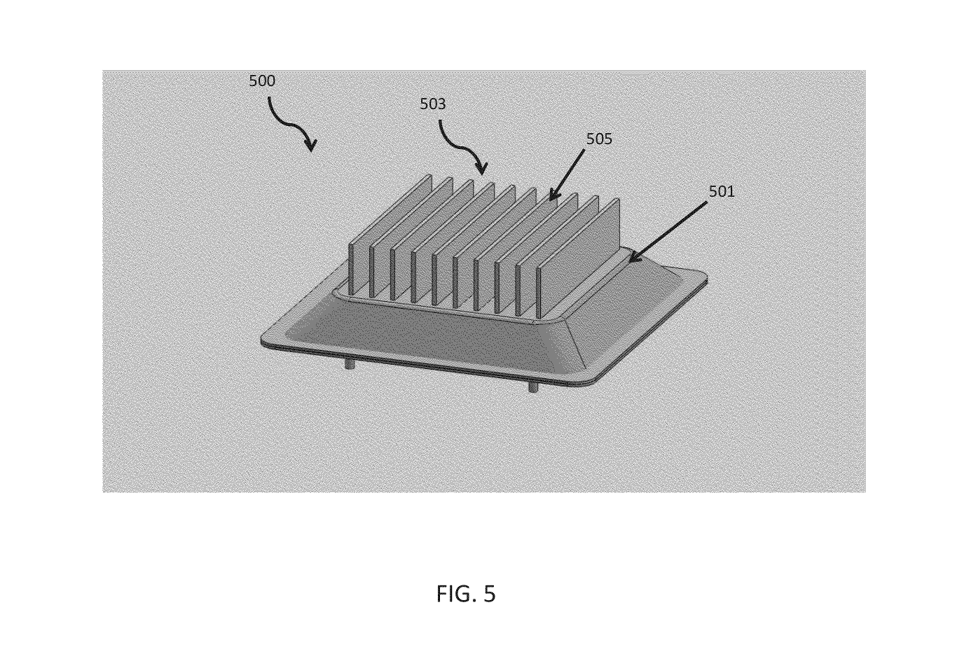

FIG. 5 illustrates an additional embodiment of a thermoelectric generator module 500 having a heat exchanger 503 directly coupled to a module cover 501. The module 500 may include an electrically interconnected package of thermoelectric converters (e.g., pairs of p-type and n-type thermoelectric legs), as shown in FIG. 3. The cover 501 (or casing) may be made of a thermally conductive material that is located over the hot side of the module 500 and conducts thermal energy from an external heat source to the hot sides of the respective thermoelectric legs. In embodiments, the cover 501 may be made of an electrically conductive material (e.g., metal or metal alloy). When the cover 501 is electrically conductive, an electrical isolator (not shown) formed of electrically insulating, thermally conductive material, such as a ceramic material, may be provided between the cover 501 and the adjacent hot end of the thermoelectric converters. For example, a ceramic coating may be provided over all or a portion of the interior surface of the cover 501 and/or over the outer surfaces of the metal headers 107 shown in FIG. 3.

A heat exchanger 503 comprises a plurality of fins 505 directly attached to the module cover 501. The heat exchange fins 505 in this embodiment comprise plate type fins, although pin type fins and combinations of plate and pin type fins could also be used. In addition, this embodiment the plate fins 505 are evenly spaced and oriented generally parallel to the direction of fluid flow, although it will be understood that other configurations may be used. For example, a gradient fin heat exchanger may be used where the fin packing fraction is varied along the direction of fluid flow and/or in a direction transverse to fluid flow, as described above.

The fins 505 may be made of a thermally-conductive material, such as a metal or metal alloy, and may be made from the same or different material than the portion of the cover 501 to which they are attached. The fins 505 may be thermally matched to the cover 501 (e.g., made from a material having a coefficient of thermal expansion (CTE) within about 10%, such as 0-5%, including 0-1% of the cover material). In embodiments, direct attachment of fins 505 to the module cover 501 may eliminate thermal interface problems between the heat exchanger and the thermoelectric generator module 500, and may significantly enhance the performance of the module 500. The fins 505 may be attached to the cover 501 using any suitable technique, such as via brazing, soldering, welding, solid state diffusion, use of a high-temperature adhesive and/or via mechanical fasteners.

In embodiments, a plurality of modules 500 having heat exchangers 503 directly attached to the module cover 501 as shown in FIG. 5 may be disposed along a path of a fluid flow (e.g., along an interior of a conduit, such as shown in FIGS. 1A and 3), and the fin packing fraction (i.e., fin density) of the fins 505 of each respective module 500 (e.g., the size the fins 505 and/or the spacing of the fins 505) may be varied along the direction of fluid flow and/or in a direction transverse to fluid flow. Thus, a relatively uniform temperature may be obtained at the hot sides of each module 500.

The preceding description of the disclosed aspects is provided to enable any person skilled in the art to make or use the present invention. Various modifications to these aspects will be readily apparent to those skilled in the art, and the generic principles defined herein may be applied to other aspects without departing from the scope of the invention. Thus, the present invention is not intended to be limited to the aspects shown herein but is to be accorded the widest scope consistent with the principles and novel features disclosed herein.

What is claimed is:

1. A power generating system, comprising:
a heat exchanger comprising an inlet, an outlet and a conduit extending along a length of the heat exchanger between the inlet and the outlet, and a plurality of thermally conductive fins provided within the conduit, a packing fraction of the fins increasing from a first packing fraction proximate the inlet to a second packing fraction proximate the outlet; and
a plurality of thermoelectric power generators positioned along the length of the heat exchanger, each thermoelectric power generator comprising a hot side, a cold side and a thermoelectric element extending therebetween, wherein the hot sides of the thermoelectric power generators are in thermal contact with the plurality of fins such that the temperature of each hot side is substantially equal along the length of the heat exchanger.

2. The system of claim 1, wherein the temperatures of the hot sides between the inlet and the outlet are each within approximately 20° C. or less of each other.

3. The system of claim 2, wherein the temperatures of the hot sides between the inlet and the outlet are each within approximately 10° C. or less of each other.

4. The system of claim 1, wherein the packing fraction of the fins increases in a stepwise manner over a length of the heat exchanger between the inlet and the outlet.

5. The system of claim 1, wherein the packing fraction of the fins is continously graded over all or a portion of a length of the heat exchanger between the inlet and the outlet.

6. The system of claim 1, wherein the packing fraction the fins is increased by varying at least one of the size of the fins and the spacing between the fins.

7. The system of claim 1, wherein the fins comprise pin fins.

8. The system of claim 1, wherein the fins comprise plate fins.

9. The system of claim 1, wherein the plurality of thermoelectric power generators comprise at least one thermoelectric power generator module comprising an electrically interconnected plurality of p-type and n-type thermoelectric material legs, each extending between a hot side and a cold side of the module, and wherein a plurality of thermally conductive fins are bonded to a surface of a protective cover of the module.

10. The system of claim 9, wherein the packing fraction of the fins in a direction substantially perpendicular to an inlet to outlet direction is lower in a first location than in a second location farther from the inlet than the first location.

11. The system of claim 9, further comprising a plurality of modules having thermally conductive fins bonded to a surface of the protective cover of each module, wherein the packing fraction of the fins increases between adjacent modules along at least one dimension of the heat exchanger.

12. The system of claim 1, wherein a temperature drop of the hot sides between the inlet and the outlet is 1-25% of the temperature of the hot side proximate the inlet.

13. The system of claim 12, wherein the temperature drop of the hot sides between the inlet and the outlet is 3-20% of the temperature of the hot side proximate to the inlet.

14. A method of generating power, comprising:
heating a fluid using a source of thermal energy;
flowing the heated fluid through a heat exchanger comprising a plurality of thermally conductive fins in thermal contact with the fluid flow, wherein a packing fraction of the fins increases in the predominant direction of fluid flow through the heat exchanger; and
generating electrical power using a plurality of thermoelectric power generators positioned along a length of the heat exchanger, each thermoelectric power generator comprising a hot side, a cold side and a thermoelectric element extending therebetween, wherein the hot sides of the thermoelectric power generators are in thermal contact with the plurality of fins such that the temperature of each hot side is substantially equal along the length of the heat exchanger.

15. The method of claim 14, wherein the temperatures of the hot sides of the thermoelectric power generators are each within approximately 20° C. or less of each other.

16. The method of claim 15, wherein the temperatures of the hot sides of the thermoelectric generators are each within approximately 10° C. or less of each other.

17. The method of claim 14, wherein the packing fraction of the fins increases in a stepwise manner in the predominant direction of fluid flow in the heat exchanger.

18. The method of claim 14, wherein the packing fraction of the fins is continously graded in the predominant direction of fluid flow in the heat exchanger.

19. The method of claim 14, wherein the packing fraction the fins is increased by varying at least one of the size of the fins and the spacing between the fins.

20. The method of claim 14, wherein the fins comprise pin fins.

21. The method of claim 14, wherein the fins comprise plate fins.

22. The method of claim 14, wherein the plurality of thermoelectric power generators comprise at least one thermoelectric power generator module comprising an electrically interconnected plurality of p-type and n-type thermoelectric material legs, each extending between a hot side and a cold side of the module, and wherein a plurality of thermally conductive fins are bonded to a surface of a protective cover of the module.

23. The method of claim 22, wherein the packing fraction of the fins in a direction substantially perpendicular to the direction of the fluid flow is lower in a first location than in a second location farther from an inlet of the fluid flow than the first location.

24. The method of claim 22, further comprising a plurality of modules having thermally conductive fins bonded to a surface of the protective cover of each module, wherein the packing fraction of the fins increases between adjacent modules along at least one dimension of the heat exchanger.

25. A thermoelectric module, comprising:
an electrically interconnected plurality of p-type and n-type thermoelectric material legs, wherein each leg extends between a first side and a second side of the module;
a cover located over the thermoelectric material legs on a first side of the module and configured to conduct thermal energy from an external heat source to the thermoelectric material legs; and
a plurality of thermally conductive fins directly attached to an outer surface of the module cover.

26. The thermoelectric module of claim 25, wherein the fins comprise plate fins.

27. The thermoelectric module of claim 26, wherein the fins and the at least the outer surface of the module cover comprise a metal or metal alloy.

28. The thermoelectric module of claim 27, wherein the fins are attached to the outer surface of the module cover via at least one of brazing, welding, soldering and solid state diffusion.

29. A method of generating electrical energy using a thermoelectric module comprising a plurality of thermoelectric material legs having a hot side and a cold side, comprising:
conducting heat from a heat source to the hot side of each of the thermoelectric material legs via a plurality of thermally conductive fins directly attached to an outer surface of a module cover located over the hot sides of the legs to provide a temperature differential between the hot side and the cold side of the legs; and
generating electricity from the plurality of thermoelectric material legs using the temperature differential.
